(19) United States
(12) Patent Application Publication
(10) Pub. No.: US 2026/0358585 A1
(43) Pub. Date: Nov. 12, 2026

(54) LOCALIZED COOLING ASSEMBLIES AND METHODS FOR PLUGGABLE OPTICAL MODULES

(71) Applicant: Ciena Corporation, Hanover, MD (US)

(72) Inventors: Behzad Mohajer, Burnaby (CA); Hamed Sadeghi, Kanata (CA)

(21) Appl. No.: 19/199,510

(22) Filed: May 6, 2025

(51) Int. Cl. G02B 6/42; H05K 7/20

(52) U.S. Cl. CPC G02B 6/4269; H05K 7/20254; H05K 7/20272; H05K 7/20436

(57) ABSTRACT

A pluggable optical module cooling assembly including a liquid cold plate attached to or integrated with a pluggable optical module including a component that generates a concentrated heat load. The liquid cold plate defines a plurality of coolant channels and includes one or more of: a pedestal protruding towards or into the pluggable optical module, an internal cavity machined or formed into the pedestal and in fluid communication with the plurality of coolant channels, a plurality of fins or protruding structures disposed in or integrated into the plurality of channels and/or the internal cavity, and a slotted or perforated jet impingement plate disposed within one of the plurality of channels coincident with a portion of the internal cavity to generate targeted coolant jets or flows that directly impact a floor of the internal cavity and the plurality of fins or protruding structures, when used.

### TECHNICAL FIELD

The present disclosure relates generally to the telecommunications and networking fields. More particularly, the present disclosure relates to localized cooling assemblies and methods for pluggable optical modules (POMs).

### BACKGROUND

The accelerating demand for high-speed connectivity has driven the development of advanced small form factor POMs. These POMs integrate high-power silicon dies, lasers, and photonic components into compact packages, functioning as “systems-in-a-plug” with high-bandwidth and extended-reach capabilities. However, these innovations bring extreme thermal challenges, with heat flux densities that exceed the capabilities of existing cooling solutions.

As power densities and heat dissipation demands increase, localized hotspots in the POMs pose significant challenges to reliable operation-especially those on digital signal processor (DSP) dies, where very high heat fluxes are concentrated in very small areas on the dies. While conventional air cooling (e.g., heatsinks) and indirect liquid cooling (e.g., cold plates) provide bulk cooling for the plug body, they struggle to effectively manage these intense, localized heat loads.

The present background is provided as illustrative environmental context only and should not be construed to be limiting in any manner. The principles and concepts of the present disclosure may be applied in other environmental texts equally, without limitation.

### SUMMARY

The present disclosure relates to localized cooling within the body and integrated or attached cold plate of a POM (i.e., a liquid-cooled plug), focusing on addressing high heat fluxes and hotspots in extremely confined spaces, particularly on DSP dies and/or laser diodes, for example.

In some embodiments, the present disclosure provides a pluggable optical module cooling assembly including a liquid cold plate adapted to be attached to or integrated with a pluggable optical module including a component that generates a concentrated heat load within the pluggable optical module, where the liquid cold plate defines a plurality of coolant channels within the liquid cold plate, and where the liquid cold plate includes one or more of:
a pedestal protruding from the liquid cold plate towards or into the pluggable optical module coincident with the concentrated heat load,
an internal cavity machined or formed into the pedestal and in fluid communication with the plurality of coolant channels to bring coolant closer to the concentrated heat load,
a plurality of fins or protruding structures disposed in or integrated into the plurality of channels and/or the internal cavity to increase cooling surface area of the plurality of channels and/or the internal cavity, and
a slotted or perforated jet impingement plate disposed within one of the plurality of channels coincident with a portion of the internal cavity to generate targeted coolant jets or flows that directly impact a floor of the internal cavity and the plurality of fins or protruding structures, when used.

In some embodiments, the plurality of coolant channels are linear coolant channels formed by one or more internal divider structures disposed within the liquid cold plate and include at least a cold coolant channel, a transition coolant channel, and a hot coolant channel. In some embodiments, the pedestal is disposed near an end of the liquid cold plate and the pluggable optical module. In some embodiments, the pedestal is disposed at a middle portion of the liquid cold plate and the pluggable optical module. In some embodiments, the plurality of fins or protruding structures include a plurality of linear fins. In some embodiments, the slotted or perforated jet impingement plate is inserted within the one of the plurality of channels coincident with the portion of the internal cavity. In some embodiments, the slotted or perforated jet impingement plate includes a divider portion that separates a cold coolant channel from a hot coolant channel of the plurality of channels. In some embodiments, the slotted or perforated jet impingement plate sits on a shoulder structure formed within the portion of the internal cavity. In some embodiments, the slotted or perforated jet impingement plate is integrally formed within the one of the plurality of channels coincident with the portion of the internal cavity.

In some embodiments, the present disclosure provides a pluggable optical module assembly including a pluggable optical module including a component that generates a concentrated heat load within the pluggable optical module and a liquid cold plate attached to or integrated with the pluggable optical module, where the liquid cold plate defines a plurality of coolant channels within the liquid cold plate, and where the liquid cold plate includes one or more of:
a pedestal protruding from the liquid cold plate towards or into the pluggable optical module coincident with the concentrated heat load,
an internal cavity machined or formed into the pedestal and in fluid communication with the plurality of coolant channels to bring coolant closer to the concentrated heat load,
a plurality of fins or protruding structures disposed in or integrated into the plurality of channels and/or the internal cavity to increase cooling surface area of the plurality of channels and/or the internal cavity, and
a slotted or perforated jet impingement plate disposed within one of the plurality of channels coincident with a portion of the internal cavity to generate targeted coolant jets or flows that directly impact a floor of the internal cavity and the plurality of fins or protruding structures, when used.

In some embodiments, the component is a digital signal processor or a laser diode. In some embodiments, the plurality of coolant channels are linear coolant channels formed by one or more internal divider structures disposed within the liquid cold plate and include at least a cold coolant channel, a transition coolant channel, and a hot coolant channel. In some embodiments, the pedestal is disposed near an end of the liquid cold plate and the pluggable optical module. In some embodiments, the pedestal is disposed at a middle portion of the liquid cold plate and the pluggable optical module. In some embodiments, the plurality of fins or protruding structures include a plurality of linear fins. In some embodiments, the slotted or perforated jet impingement plate is inserted within the one of the plurality of channels coincident with the portion of the internal cavity. In some embodiments, the slotted or perforated jet impingement plate includes a divider portion that separates a cold coolant channel from a hot coolant channel of the plurality of channels. In some embodiments, the slotted or perforated jet impingement plate sits on a shoulder structure formed within the portion of the internal cavity. In some embodiments, the slotted or perforated jet impingement plate is integrally formed within the one of the plurality of channels coincident with the portion of the internal cavity.

In some embodiments, the present disclosure provides a method for providing a pluggable optical module cooling assembly including providing a liquid cold plate adapted to be attached to or integrated with a pluggable optical module including a component that generates a concentrated heat load within the pluggable optical module, where the liquid cold plate defines a plurality of coolant channels within the liquid cold plate, and where providing the liquid cold plate includes providing one or more of:
a pedestal protruding from the liquid cold plate towards or into the pluggable optical module coincident with the concentrated heat load,
an internal cavity machined or formed into the pedestal and in fluid communication with the plurality of coolant channels to bring coolant closer to the concentrated heat load,
a plurality of fins or protruding structures disposed in or integrated into the plurality of channels and/or the internal cavity to increase cooling surface area of the plurality of channels and/or the internal cavity, and
a slotted or perforated jet impingement plate disposed within one of the plurality of channels coincident with a portion of the internal cavity to generate targeted coolant jets or flows that directly impact a floor of the internal cavity and the plurality of fins or protruding structures, when used.

It will be readily apparent to those of ordinary skill in the art that aspects and features of the disclosed embodiments may be included, omitted, or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate.

FIG. 1 illustrates a POM cooling assembly utilizing a riding heatsink coupled to a cage that is adapted to receive the POM, such that a dry/sliding thermal interface is provided between the POM and the riding heatsink.

FIG. 2 illustrates a POM cooling assembly utilizing a riding cold plate coupled to the cage that is adapted to receive the POM, such that a dry/sliding thermal interface is again provided between the POM and the riding cold plate.

FIG. 3 illustrates a POM cooling assembly utilizing a liquid cold plate that is integrated with or attached to the POM, such that no dry/sliding thermal interface is required between the POM and the liquid cold plate.

FIG. 4 illustrates the POM cooling assembly again utilizing the liquid cold plate that is integrated with or attached to the POM, such that no dry/sliding thermal interface is required between the POM and the liquid cold plate, highlighting quick connects/disconnects provided between the POM cooling assembly an a liquid cooling plenum of an associated module.

FIG. 5 illustrates an embodiment of the liquid cold plate of the POM cooling assembly and POM of the present disclosure, utilizing linear cold and hot cooling channels.

FIG. 6 illustrates an embodiment of the liquid cold plate of the POM cooling assembly and POM of the present disclosure, utilizing linear cold and hot cooling channels incorporating linear fins or other thermal transfer enhancement structures.

FIG. 7 illustrates an embodiment of the liquid cold plate of the POM cooling assembly and POM of the present disclosure, utilizing linear cold and hot cooling channels and incorporating an (inserted) jet impingement plate for enhancing the cooling of the adjacent concentrated heat loads near a module faceplate (i.e., nose) end of the POM.

FIG. 8 illustrates an embodiment of the liquid cold plate of the POM cooling assembly and POM of the present disclosure, utilizing linear cold and hot cooling channels and incorporating the (removed) jet impingement plate for enhancing the cooling of the adjacent concentrated heat loads near the module faceplate (i.e., nose) end of the POM.

FIG. 9 illustrates an embodiment of the liquid cold plate of the POM cooling assembly and POM of the present disclosure, utilizing linear cold and hot cooling channels and incorporating an (inserted) jet impingement plate for enhancing the cooling of the adjacent concentrated heat loads near the middle of the POM.

FIG. 10 illustrates an embodiment of the liquid cold plate of the POM cooling assembly and POM of the present disclosure, utilizing linear cold and hot cooling channels and incorporating the (removed) jet impingement plate for enhancing the cooling of the adjacent concentrated heat loads near the middle of the POM.

FIG. 11 illustrates an embodiment of the liquid cold plate of the POM cooling assembly and POM of the present disclosure, utilizing linear cold and hot cooling channels and incorporating an integral jet impingement plate for enhancing the cooling of the adjacent concentrated heat loads near the nose end of the POM.

FIG. 12 illustrates an embodiment of the liquid cold plate of the POM cooling assembly and POM of the present disclosure, utilizing linear cold and hot cooling channels and incorporating the integral jet impingement plate for enhancing the cooling of the adjacent concentrated heat loads near the nose of the POM.

FIG. 13 illustrates an embodiment of the liquid cold plate of the POM cooling assembly and POM of the present disclosure, utilizing linear cold and hot cooling channels incorporating linear fins or other thermal transfer enhancement structures in the hollow pedestal for enhancing the cooling of the adjacent concentrated heat loads near the nose of the POM.

FIG. 14 illustrates an embodiment of the liquid cold plate of the POM cooling assembly and POM of the present disclosure, utilizing linear cold and hot cooling channels and incorporating the integral slotted jet impingement plate for enhancing the cooling of the adjacent concentrated heat loads near the nose of the POM, as well as the (coarser) linear fins or other thermal transfer enhancement structures in the hollow pedestal for enhancing the cooling of the adjacent concentrated heat loads.

FIG. 15 illustrates an embodiment of the liquid cold plate of the POM cooling assembly and POM of the present disclosure, utilizing linear cold and hot cooling channels and incorporating the integral slotted jet impingement plate for enhancing the cooling of the adjacent concentrated heat loads near the nose of the POM, as well as the (finer) linear fins or other thermal transfer enhancement structures in the hollow pedestal for enhancing the cooling of the adjacent concentrated heat loads.

FIG. 16 illustrates an embodiment of the liquid cold plate of the POM cooling assembly and POM of the present disclosure, utilizing linear cold and hot cooling channels and incorporating the integral perforated jet impingement plate for enhancing the cooling of the adjacent concentrated heat loads near the nose of the POM, as well as the (finer) linear fins or other thermal transfer enhancement structures in the hollow pedestal for enhancing the cooling of the adjacent concentrated heat loads.

FIG. 17 illustrates an embodiment of a method for providing the POM cooling assembly and POM of the present disclosure.

It will be readily apparent to those of ordinary skill in the art that aspects and features of the illustrated embodiments may be included, omitted, or combined as desired in a given application, without limitation.

### DETAILED DESCRIPTION

Again, the present disclosure relates to localized cooling within the body and integrated or attached cold plate of a POM (i.e., a liquid-cooled plug), focusing on addressing high heat fluxes and hotspots in extremely confined spaces, particularly on DSP dies and/or laser diodes, for example.

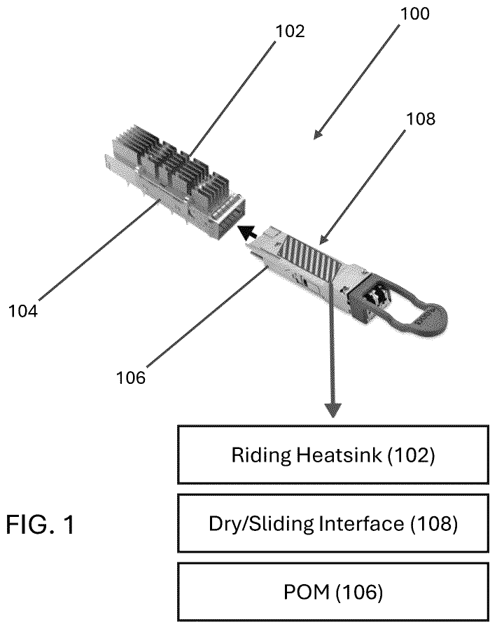

FIG. 1 illustrates a POM cooling assembly 100 utilizing a riding heatsink 102 coupled to a cage 104 that is adapted to receive the POM 106, such that a dry/sliding thermal interface 108 is provided between the POM 106 and the riding heatsink 102. This dry-sliding thermal interface 108 through the cage 104 results in a thermal penalty and may result in mechanical wear on the body of the POM 106. Further, this arrangement, relying on a cooling air flow across the riding heatsink 102, inadequately cools localized hotspots within the POM 106, such as those associated with DSP dies, laser diodes, and the like within the POM 106.

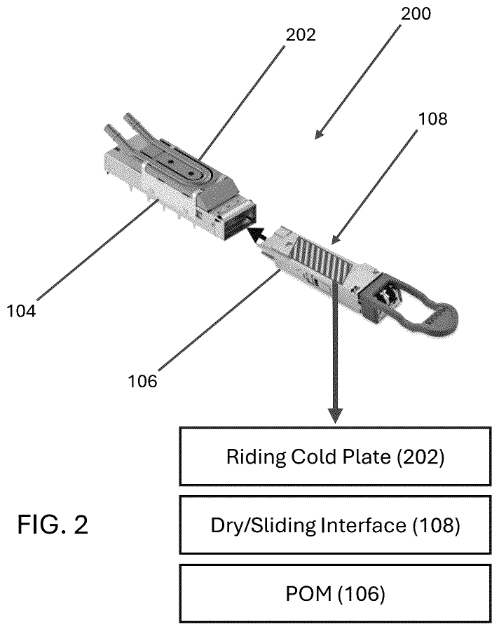

FIG. 2 illustrates a POM cooling assembly 200 utilizing a riding cold plate 202 coupled to the cage 104 that is adapted to receive the POM 106, such that a dry/sliding thermal interface 108 is again provided between the POM 106 and the riding cold plate 202. Again, this dry-sliding thermal interface 108 through the cage 104 results in a thermal penalty and may result in mechanical wear on the body of the POM 106. Further, this arrangement, relying on a cooling liquid flow through the riding cold plate 202, inadequately cools localized hotspots within the POM 106, such as those associated with DSP dies, laser diodes, and the like within the POM 106.

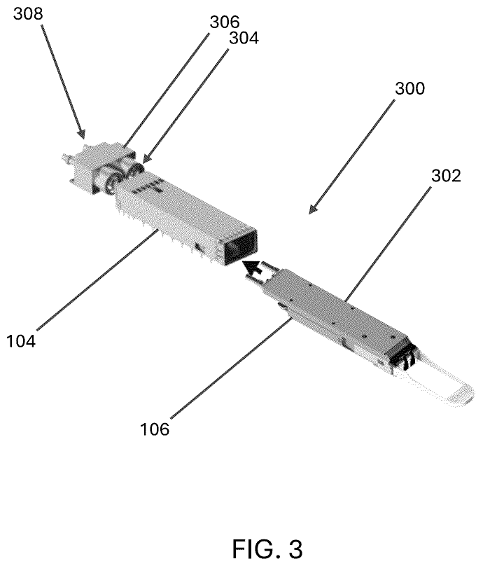

FIG. 3 illustrates a POM cooling assembly 300 utilizing a liquid cold plate 302 that is integrated with or attached to the POM 106, such that no dry/sliding thermal interface 108 is required between the POM 106 and the liquid cold plate 302. The elimination of the dry-sliding thermal interface 108 through the cage 104 eliminates the associated thermal penalty, as well as mechanical wear on the body of the POM 106. However, this arrangement, relying on a cooling liquid flow through the liquid cold plate 302, still inadequately cools localized hotspots within the POM 106, such as those associated with DSP dies, laser diodes, and the like within the POM 106.

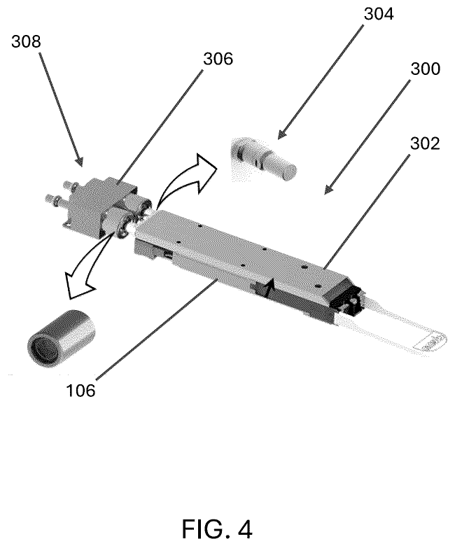

FIG. 4 illustrates the POM cooling assembly 300 again utilizing the liquid cold plate 302 that is integrated with or attached to the POM 106, such that no dry/sliding thermal interface 108 is required between the POM 106 and the liquid cold plate 302, highlighting quick connects/disconnects 304 provided between the POM cooling assembly 300 an a liquid cooling plenum 306 of an associated module 308.

The present disclosure provides a POM 106 with an integrated or attached liquid cold plate 302 designed to manage high heat fluxes and localized hotspots within the POM 106. The integrated or attached liquid cold plate 302 is designed to specifically target the high-power density areas within the body of the plug, such as the DSP die or laser diode hotspots, for example, ensuring efficient heat dissipation in confined spaces. The liquid cold plate 302 utilizes one or more of the following:
a pedestal protruding from the liquid cold plate 302 towards/into the POM 106 coincident with the concentrated heat loads in the POM 106,
a cavity machined or formed into the pedestal directly adjacent to the concentrated heat loads in the POM 106 to bring coolant closer to the concentrated heat loads, minimizing conduction and heat spreading resistances,
fins disposed in and/or integrated into the channels of the liquid cold plate 302 and/or the cavity to increase cooling surface area and improve thermal performance, and/or
a slotted or perforated jet impingement plate disposed within the one or more of the channels above the cavity to generate targeted coolant jets or flows that directly impact the cavity floor and fins, when used, further optimizing heat transfer and enhancing cooling performance.

Thermal simulations indicate that variously combining the pedestal, the cavity, the fins, and jet impingement plate reduces thermal resistance from the DSP die, laser diode, and/or the like to the coolant by over 50%. This localized cooling approach enables the cooling of higher power densities while maintaining the compact form factor of the POM 106. The pressure penalty caused by the additional features of the liquid cold plate 302 added to the coolant flow path is small compared to the primary source of pressure drop, which is the quick connect/disconnect fittings 304.

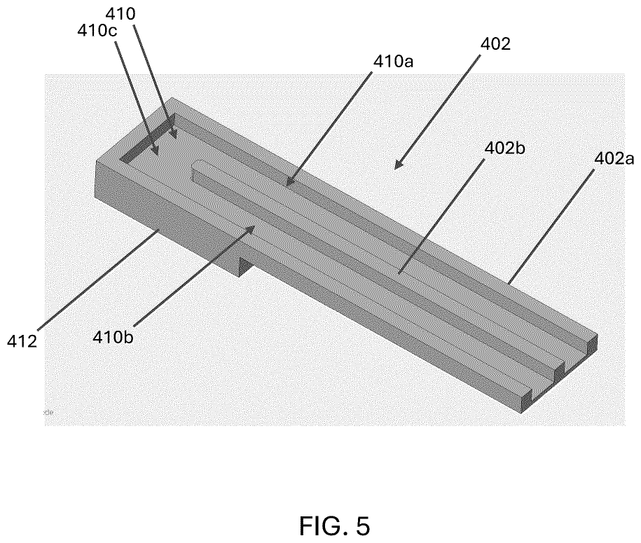

FIG. 5 illustrates an embodiment of the liquid cold plate 402 of the POM cooling assembly 300 and POM 106 of the present disclosure. The body 402a and one or more internal divider structures 402b of the liquid cold plate 402 define a plurality of coolant channels 410 within the liquid cold plate 402, including at least a cold coolant channel 410a adapted to carry cold coolant to the proximity of the hot components of the POM 106 and a hot coolant channel 410b adapted to carry hot coolant from the proximity of the hot components of the POM 106, coupled together by a transition coolant channel 410c, for example. The coolant channels 410 may be linear channels or may form a circuitous conduit forming the coolant flow path and may have any lateral profile. Although the coolant channels 410 are shown as being formed in the body 402a of the liquid cold plate 402, the coolant channels 410 may also consist of conduit sections disposed within the body 402a of the liquid cold plate 402. A pedestal 412 protrudes from the liquid cold plate 402 towards/into the POM 106 coincident with the concentrated heat loads in the POM 106. In this embodiment, the pedestal 412 is a solid structure that serves to form a thermal communication path between the coolant channels 410 of the liquid cold plate 402 and the concentrated heat loads in the POM 106. The pedestal 412 may alternatively be machined or formed to be hollow, thereby acting as a deepened portion of the coolant path or coolant reservoir that serves to bring the coolant closer to the concentrated heat loads in the POM 106, thereby enhancing the cooling of the concentrated heat loads.

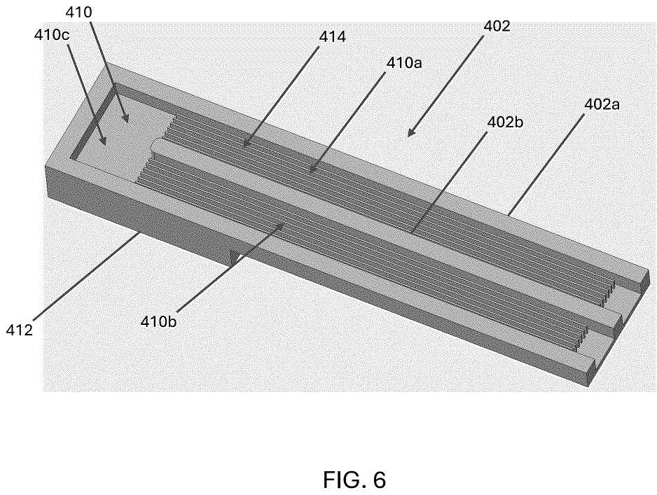

FIG. 6 illustrates another embodiment of the liquid cold plate 402 of the POM cooling assembly 300 and POM 106 of the present disclosure. Again, the body 402a and the one or more internal divider structures 402b of the liquid cold plate 402 define the plurality of coolant channels 410 within the liquid cold plate 402, including at least the cold coolant channel 410a adapted to carry cold coolant to the proximity of the hot components of the POM 106 and the hot coolant channel 410b adapted to carry hot coolant from the proximity of the hot components of the POM 106, coupled together by the transition coolant channel 410c, for example. The coolant channels 410 may be linear channels or may form a circuitous conduit forming the coolant flow path and may have any lateral profile. Although the coolant channels 410 are shown as being formed in the body 402a of the liquid cold plate 402, the coolant channels 410 may also consist of conduit sections disposed within the body 402a of the liquid cold plate 402. In this embodiment, a plurality of linear fins 414 or other thermal transfer enhancement structures are longitudinally (or otherwise) disposed within the coolant channels 410, increasing the thermal transfer surface area between the liquid cold plate 402 and the coolant, and potentially modifying the coolant flow through the liquid cold plate 402, directing and/or modifying the speed of the flow of the coolant. Again, the pedestal 412 protrudes from the liquid cold plate 402 towards/into the POM 106 coincident with the concentrated heat loads in the POM 106. In this embodiment, the pedestal 412 is a solid structure that serves to form a thermal communication path between the coolant channels 410 of the liquid cold plate 402 and the concentrated heat loads in the POM 106. Again, the pedestal 412 may alternatively be machined or formed to be hollow, thereby acting as a deepened portion of the coolant path or coolant reservoir that serves to bring the coolant closer to the concentrated heat loads in the POM 106, thereby enhancing the cooling of the concentrated heat loads.

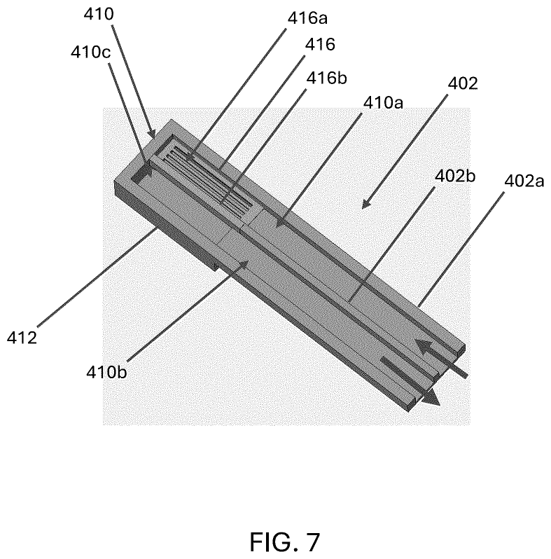

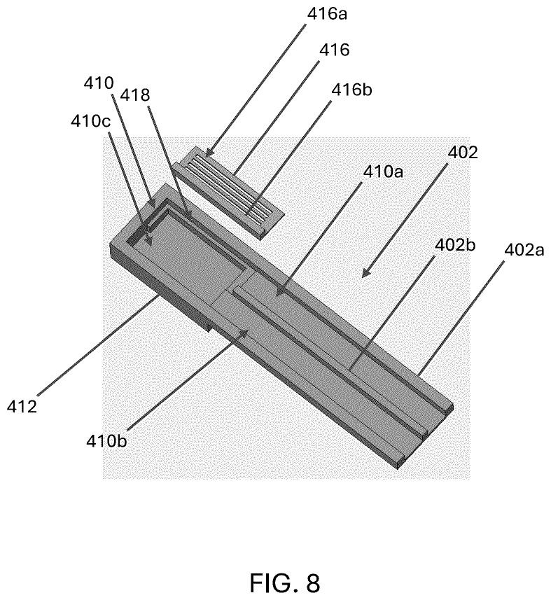

FIGS. 7 and 8 illustrate a further embodiment of the liquid cold plate 402 of the POM cooling assembly 300 and POM 106 of the present disclosure. Again, the body 402a and the one or more internal divider structures 402b of the liquid cold plate 402 define the plurality of coolant channels 410 within the liquid cold plate 402, including at least the cold coolant channel 410a adapted to carry cold coolant to the proximity of the hot components of the POM 106 and the hot coolant channel 410b adapted to carry hot coolant from the proximity of the hot components of the POM 106, coupled together by the transition coolant channel 410c, for example. The coolant channels 410 may be linear channels or may form a circuitous conduit forming the coolant flow path and may have any lateral profile. Although the coolant channels 410 are shown as being formed in the body 402a of the liquid cold plate 402, the coolant channels 410 may also consist of conduit sections disposed within the body 402a of the liquid cold plate 402. Again, the pedestal 412 protrudes from the liquid cold plate 402 towards/into the POM 106 coincident with the concentrated heat loads in the POM 106. In this embodiment, the pedestal 412 is machined or formed to be hollow, thereby acting as a deepened portion of the coolant path or coolant reservoir that serves to bring the coolant closer to the concentrated heat loads in the POM 106, thereby enhancing the cooling of the concentrated heat loads. In this embodiment, the hollow pedestal 412 is disposed at the module faceplate (i.e., nose) end of the POM 106, where the concentrated heat loads are located. A jet impingement plate 416 is disposed within the hollow pedestal 412, serving to divide the cold coolant channel 410a from the deepened portion of the pedestal 412. The jet impingement plate 416 includes a plurality of slots 416a through which coolant can flow from the cold coolant channel 410a, to the deepened portion of the pedestal 412, and to the hot coolant channel 410b, being directed and/or accelerated towards the floor of the hollow pedestal 412 and the concentrated heat loads, thereby enhancing thermal transfer. Holes, perforations, and/or the like could be used instead of the slots 416a. In this embodiment, the jet impingement plate 416 is removable and a divider portion 416b of the jet impingement plate 416 forms a portion of the internal divider structure 402b, forcing all coolant to flow from the cold coolant channel 410a, through the jet impingement plate 416, to the deepened portion of the pedestal 412, and to the hot coolant channel 410b. The jet impingement plate sits on a shoulder structure 418 provided within the hollow pedestal 412.

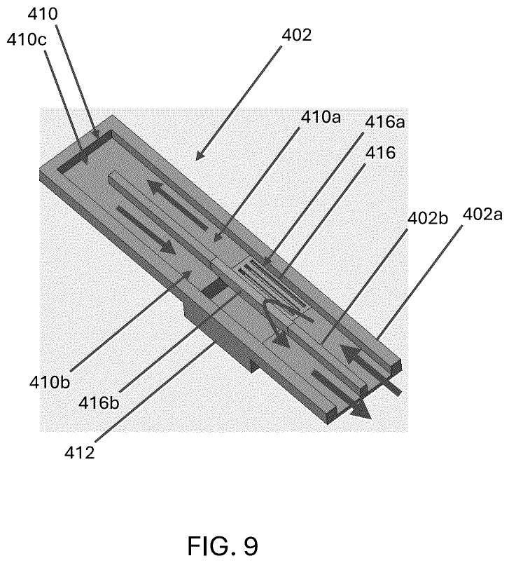

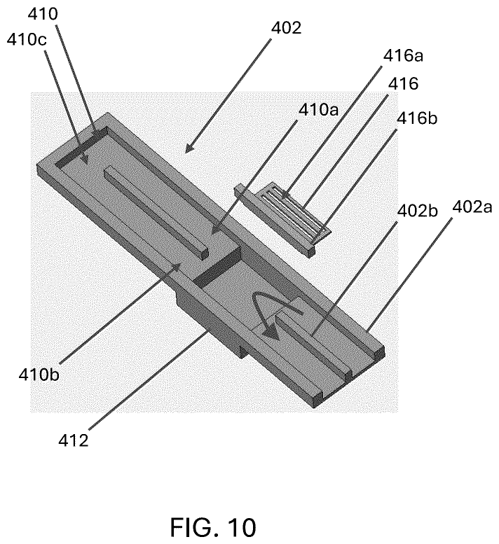

FIGS. 9 and 10 illustrate a still further embodiment of the liquid cold plate 402 of the POM cooling assembly 300 and POM 106 of the present disclosure. Again, the body 402a and the one or more internal divider structures 402b of the liquid cold plate 402 define the plurality of coolant channels 410 within the liquid cold plate 402, including at least the cold coolant channel 410a adapted to carry cold coolant to the proximity of the hot components of the POM 106 and the hot coolant channel 410b adapted to carry hot coolant from the proximity of the hot components of the POM 106, coupled together by the transition coolant channel 410c, for example. The coolant channels 410 may be linear channels or may form a circuitous conduit forming the coolant flow path and may have any lateral profile. Although the coolant channels 410 are shown as being formed in the body 402a of the liquid cold plate 402, the coolant channels 410 may also consist of conduit sections disposed within the body 402a of the liquid cold plate 402. Again, the pedestal 412 protrudes from the liquid cold plate 402 towards/into the POM 106 coincident with the concentrated heat loads in the POM 106. In this embodiment, the pedestal 412 is machined or formed to be hollow, thereby acting as a deepened portion of the coolant path or coolant reservoir that serves to bring the coolant closer to the concentrated heat loads in the POM 106, thereby enhancing the cooling of the concentrated heat loads. In this embodiment, the hollow pedestal 412 is disposed near the middle of the POM 106, where the concentrated heat loads are located. A jet impingement plate 416 is disposed within the hollow pedestal 412, serving to divide the cold coolant channel 410a from the deepened portion of the pedestal 412. The jet impingement plate 416 includes a plurality of slots 416a through which coolant can flow from the cold coolant channel 410a, to the deepened portion of the pedestal 412, and to the hot coolant channel 410b, being directed and/or accelerated towards the floor of the hollow pedestal 412 and the concentrated heat loads, thereby enhancing thermal transfer. Holes, perforations, and/or the like could be used instead of the slots 416a. In this embodiment, the jet impingement plate 416 is removable and a divider portion 416b of the jet impingement plate 416 forms a portion of the internal divider structure 402b, forcing some coolant to flow from the cold coolant channel 410a, through the jet impingement plate 416, to the deepened portion of the pedestal 412, and to the hot coolant channel 410b, while some coolant continues to flow from the cold coolant channel 410a to the hot coolant channel 410b through the transition coolant channel 410c near the nose of the POM 106, remote from the hollow pedestal 412. The jet impingement plate may again sit on a shoulder structure 418 provided within the hollow pedestal 412.

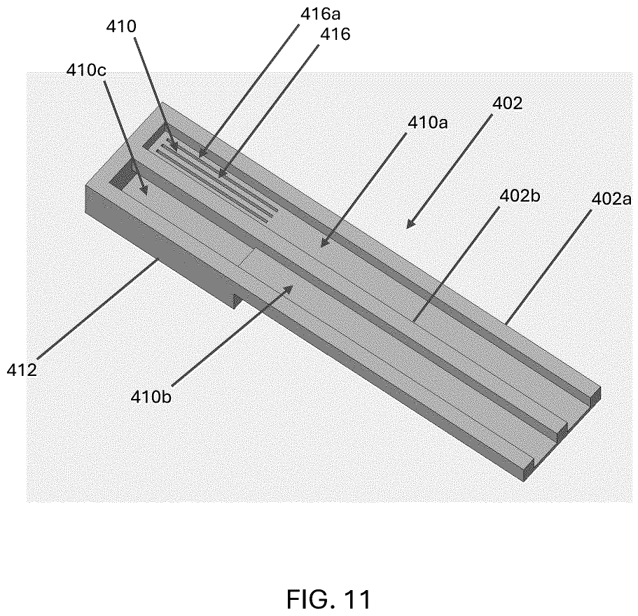

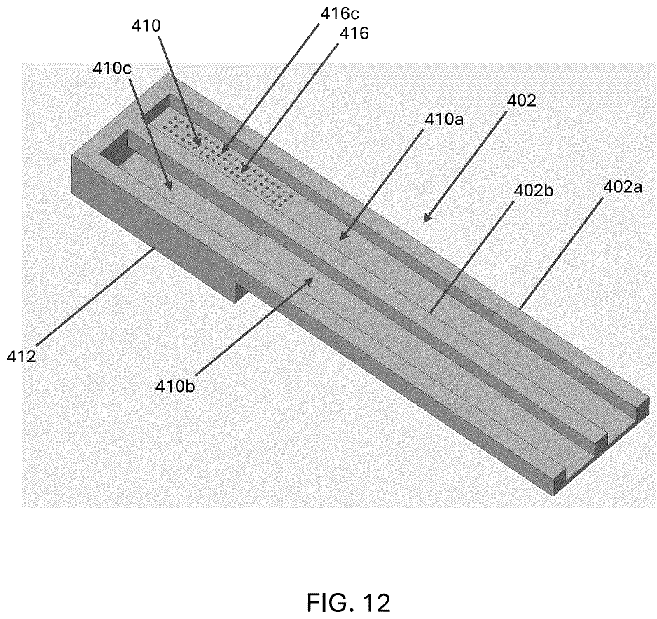

FIGS. 11 and 12 illustrate a still further embodiment of the liquid cold plate 402 of the POM cooling assembly 300 and POM 106 of the present disclosure. Again, the body 402a and the one or more internal divider structures 402b of the liquid cold plate 402 define the plurality of coolant channels 410 within the liquid cold plate 402, including at least the cold coolant channel 410a adapted to carry cold coolant to the proximity of the hot components of the POM 106 and the hot coolant channel 410b adapted to carry hot coolant from the proximity of the hot components of the POM 106, coupled together by the transition coolant channel 410c, for example. The coolant channels 410 may be linear channels or may form a circuitous conduit forming the coolant flow path and may have any lateral profile. Although the coolant channels 410 are shown as being formed in the body 402a of the liquid cold plate 402, the coolant channels 410 may also consist of conduit sections disposed within the body 402a of the liquid cold plate 402. Again, the pedestal 412 protrudes from the liquid cold plate 402 towards/into the POM 106 coincident with the concentrated heat loads in the POM 106. In this embodiment, the pedestal 412 is machined or formed to be hollow, thereby acting as a deepened portion of the coolant path or coolant reservoir that serves to bring the coolant closer to the concentrated heat loads in the POM 106, thereby enhancing the cooling of the concentrated heat loads. In this embodiment, the hollow pedestal 412 is disposed near the nose of the POM 106, where the concentrated heat loads are located. A jet impingement plate 416 is integrally formed within the hollow pedestal 412, serving to divide the cold coolant channel 410a from the deepened portion of the pedestal 412. The jet impingement plate 416 includes a plurality of slots 416a (FIG. 11) or holes/perforations 416c (FIG. 12) through which coolant can flow from the cold coolant channel 410a, to the deepened portion of the pedestal 412, and to the hot coolant channel 410b, being directed and/or accelerated towards the floor of the hollow pedestal 412 and the concentrated heat loads, thereby enhancing thermal transfer. In this embodiment, the internal divider structure 402b, forces all coolant to flow from the cold coolant channel 410a, through the jet impingement plate 416, to the deepened portion of the pedestal 412, and to the hot coolant channel 410b, under the internal divider structure 402b.

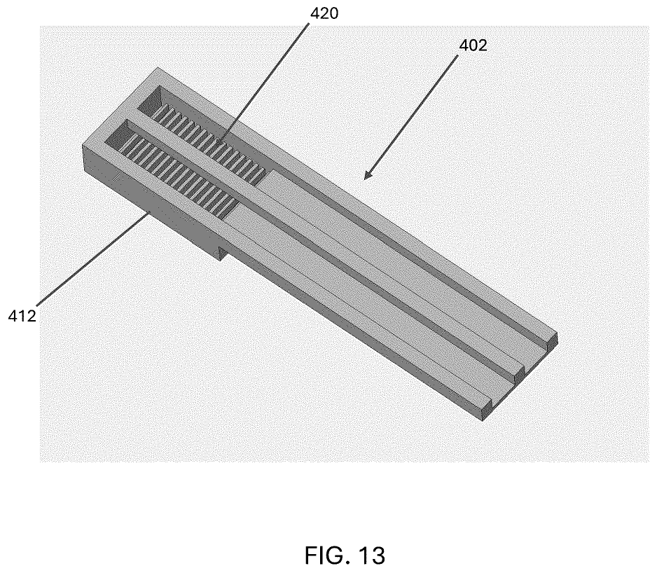

FIG. 13 illustrates an embodiment of the liquid cold plate 402 of the POM cooling assembly 300 and POM 106 of the present disclosure, utilizing linear cold and hot cooling channels 410a, 410b incorporating linear fins 420 or other thermal transfer enhancement structures in the hollow pedestal 412 for enhancing the cooling of the adjacent concentrated heat loads near the nose of the POM 106. These linear fins can have any suitable size and spacing within the pedestal envelope provided, balancing thermal transfer and coolant flow considerations.

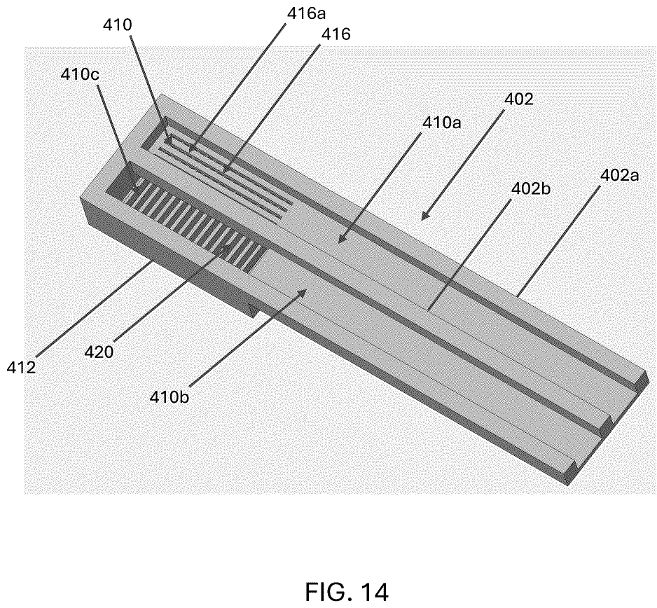

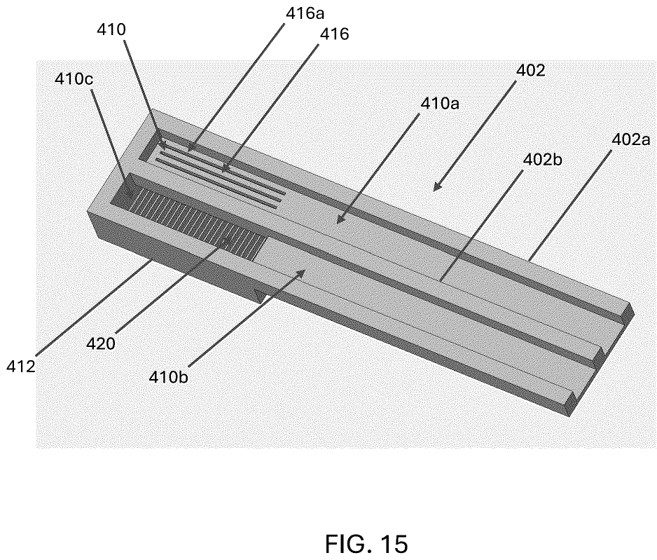

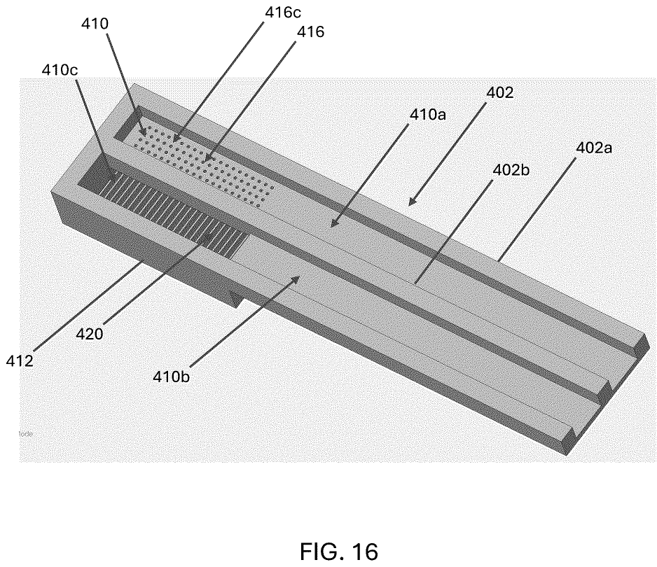

FIGS. 14-16 illustrate a still further embodiment of the liquid cold plate 402 of the POM cooling assembly 300 and POM 106 of the present disclosure. Again, the body 402a and the one or more internal divider structures 402b of the liquid cold plate 402 define the plurality of coolant channels 410 within the liquid cold plate 402, including at least the cold coolant channel 410a adapted to carry cold coolant to the proximity of the hot components of the POM 106 and the hot coolant channel 410b adapted to carry hot coolant from the proximity of the hot components of the POM 106, coupled together by the transition coolant channel 410c, for example. The coolant channels 410 may be linear channels or may form a circuitous conduit forming the coolant flow path and may have any lateral profile. Although the coolant channels 410 are shown as being formed in the body 402a of the liquid cold plate 402, the coolant channels 410 may also consist of conduit sections disposed within the body 402a of the liquid cold plate 402. Again, the pedestal 412 protrudes from the liquid cold plate 402 towards/into the POM 106 coincident with the concentrated heat loads in the POM 106. In this embodiment, the pedestal 412 is machined or formed to be hollow, thereby acting as a deepened portion of the coolant path or coolant reservoir that serves to bring the coolant closer to the concentrated heat loads in the POM 106, thereby enhancing the cooling of the concentrated heat loads. In this embodiment, the hollow pedestal 412 is disposed near the nose of the POM 106, where the concentrated heat loads are located. The jet impingement plate 416 is integrally formed within the hollow pedestal 412, serving to divide the cold coolant channel 410a from the deepened portion of the pedestal 412. The jet impingement plate 416 includes the plurality of slots 416a (FIGS. 14 and 15) or holes/perforations 416c (FIG. 16) through which coolant can flow from the cold coolant channel 410a, to the deepened portion of the pedestal 412, and to the hot coolant channel 410b, being directed and/or accelerated towards the floor of the hollow pedestal 412 and the concentrated heat loads, thereby enhancing thermal transfer. In this embodiment, the internal divider structure 402b, forces all coolant to flow from the cold coolant channel 410a, through the jet impingement plate 416, to the deepened portion of the pedestal 412, and to the hot coolant channel 410b, under the internal divider structure 402b. In this embodiment, the hollow pedestal 412 includes the linear fins 420 or other thermal transfer enhancement structures for enhancing the cooling of the adjacent concentrated heat loads near the nose of the POM 106. These linear fins can have any suitable size and spacing, from coarser (FIG. 14) to finer (FIGS. 15 and 16), within the pedestal envelope provided, balancing thermal transfer and coolant flow considerations.

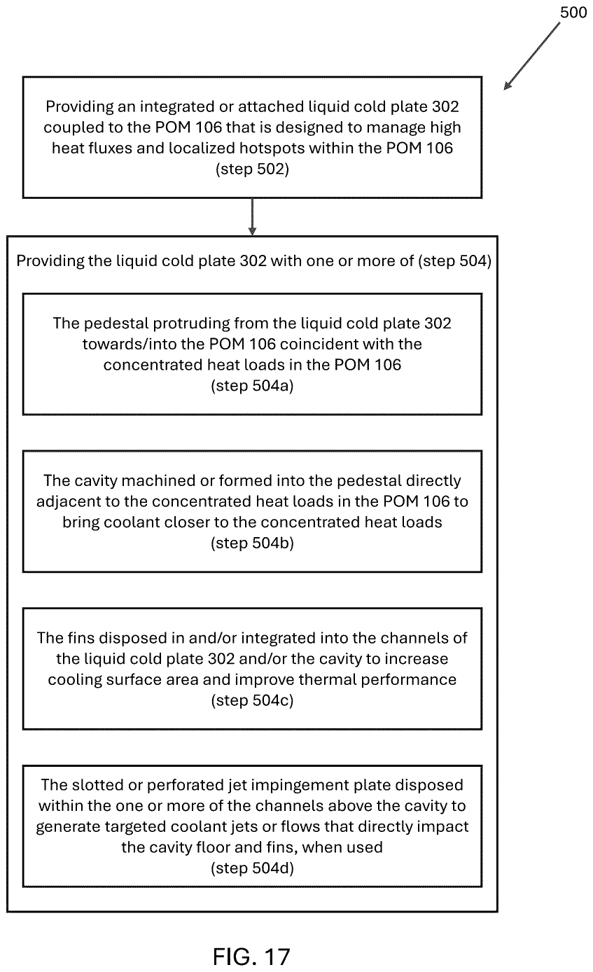

FIG. 17 illustrates an embodiment of a method 500 for providing the POM cooling assembly 300 and POM 106 of the present disclosure. The method 500 includes providing an integrated or attached liquid cold plate 302 coupled to the POM 106 that is designed to manage high heat fluxes and localized hotspots within the POM 106 (step 502). The integrated or attached liquid cold plate 302 is designed to specifically target the high-power density areas within the body of the plug, such as the DSP die or laser diode hotspots, for example, ensuring efficient heat dissipation in confined spaces. The method 500 also includes providing the liquid cold plate 302 with one or more of the following (step 504):
the pedestal protruding from the liquid cold plate 302 towards/into the POM 106 coincident with the concentrated heat loads in the POM 106 (step 504a),
the cavity machined or formed into the pedestal directly adjacent to the concentrated heat loads in the POM 106 to bring coolant closer to the concentrated heat loads, minimizing conduction and heat spreading resistances (step 504b),
the fins disposed in and/or integrated into the channels of the liquid cold plate 302 and/or the cavity to increase cooling surface area and improve thermal performance (step 504c), and/or
the slotted or perforated jet impingement plate disposed within the one or more of the channels above the cavity to generate targeted coolant jets or flows that directly impact the cavity floor and fins, when used, further optimizing heat transfer and enhancing cooling performance (step 504d).

Although the present disclosure is illustrated and described with reference to specific embodiments and examples, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

1. A pluggable optical module cooling assembly comprising
a liquid cold plate adapted to be integrated with a pluggable optical module comprising a component that generates a concentrated heat load within the pluggable optical module, wherein the liquid cold plate defines a plurality of coolant channels within the liquid cold plate, and wherein the liquid cold plate comprises one or more of
an internal cavity machined or formed into a pedestal protruding from the liquid cold plate and in fluid communication with the plurality of coolant channels to bring coolant closer to the concentrated heat load,
a plurality of fins or protruding structures disposed in or integrated into at least one of the plurality of coolant channels to increase a cooling surface area, and
when the internal cavity is utilized, a plurality of fins or protruding structures disposed in or integrated into one or more of the internal cavity or the at least one of the plurality of coolant channels to increase a cooling surface area.

2. The pluggable optical module cooling assembly of claim 1, wherein the plurality of coolant channels are linear coolant channels formed by one or more internal divider structures disposed within the liquid cold plate and comprise at least a cold coolant channel, a transition coolant channel, and a hot coolant channel.

3. The pluggable optical module cooling assembly of claim 1, wherein the pedestal protrudes from the liquid cold plate towards or into the pluggable optical module coincident with the concentrated heat load.

4. The pluggable optical module cooling assembly of claim 1, wherein, when the internal cavity is utilized, the liquid cold plate further comprises a slotted or perforated jet impingement plate disposed within the liquid cold plate coincident with at least a portion of the internal cavity to generate targeted coolant jets or flows into the internal cavity.

5. The pluggable optical module cooling assembly of claim 1, wherein the plurality of fins or protruding structures comprise a plurality of linear fins.

6. The pluggable optical module cooling assembly of claim 4, wherein the slotted or perforated jet impingement plate is inserted within at least one of the plurality of coolant channels coincident with the at least the portion of the internal cavity.

7. The pluggable optical module cooling assembly of claim 6, wherein the slotted or perforated jet impingement plate comprises a divider portion that separates a cold coolant channel from a hot coolant channel of the plurality of coolant channels.

8. The pluggable optical module cooling assembly of claim 6, wherein the slotted or perforated jet impingement plate sits on a shoulder structure formed within the at least the portion of the internal cavity.

9. The pluggable optical module cooling assembly of claim 4, wherein the slotted or perforated jet impingement plate is integrally formed within at least one of the plurality of coolant channels coincident with the portion of the internal cavity.

10. A pluggable optical module assembly comprising
a pluggable optical module comprising a component that generates a concentrated heat load within the pluggable optical module, and
a liquid cold plate integrated with the pluggable optical module, wherein the liquid cold plate defines a plurality of coolant channels within the liquid cold plate, and wherein the liquid cold plate comprises one or more of
an internal cavity machined or formed into a pedestal protruding from the liquid cold plate and in fluid communication with the plurality of coolant channels to bring coolant closer to the concentrated heat load,
a plurality of fins or protruding structures disposed in or integrated into at least one of the plurality of coolant channels to increase a cooling surface area, and
when the internal cavity is utilized, a plurality of fins or protruding structures disposed in or integrated into one or more of the internal cavity or the at least one of the plurality of coolant channels to increase a cooling surface area.

11. The pluggable optical module assembly of claim 10, wherein the component is a digital signal processor or a laser diode.

12. The pluggable optical module assembly of claim 10, wherein the plurality of coolant channels are linear coolant channels formed by one or more internal divider structures disposed within the liquid cold plate and comprise at least a cold coolant channel, a transition coolant channel, and a hot coolant channel.

13. The pluggable optical module assembly of claim 10, wherein the pedestal protrudes from the liquid cold plate towards or into the pluggable optical module coincident with the concentrated heat load.

14. The pluggable optical module assembly of claim 10, wherein, when the internal cavity is utilized, the liquid cold plate further comprises a slotted or perforated jet impingement plate disposed within the liquid cold plate coincident with at least a portion of the internal cavity to generate targeted coolant jets or flows into the internal cavity.

15. The pluggable optical module assembly of claim 10, wherein the plurality of fins or protruding structures comprise a plurality of linear fins.

16. The pluggable optical module assembly of claim 14, wherein the slotted or perforated jet impingement plate is inserted within at least one of the plurality of coolant channels coincident with the at least the portion of the internal cavity.

17. The pluggable optical module assembly of claim 16, wherein the slotted or perforated jet impingement plate comprises a divider portion that separates a cold coolant channel from a hot coolant channel of the plurality of coolant channels.

18. The pluggable optical module cooling of claim 16, wherein the slotted or perforated jet impingement plate sits on a shoulder structure formed within the at least the portion of the internal cavity.

19. The pluggable optical module assembly of claim 14, wherein the slotted or perforated jet impingement plate is integrally formed within at least one of the plurality of coolant channels coincident with the at least the portion of the internal cavity.

20. A method for providing a pluggable optical module cooling assembly comprising
providing a liquid cold plate adapted to be integrated with a pluggable optical module comprising a component that generates a concentrated heat load within the pluggable optical module, wherein the liquid cold plate defines a plurality of coolant channels within the liquid cold plate, and wherein providing the liquid cold plate comprises providing one or more of
an internal cavity machined or formed into a pedestal protruding from the liquid cold plate and in fluid communication with the plurality of coolant channels to bring coolant closer to the concentrated heat load,
a plurality of fins or protruding structures disposed in or integrated into at least one of the plurality of coolant channels to increase a cooling surface area,
when the internal cavity is utilized, a plurality of fins or protruding structures disposed in or integrated into one or more of the internal cavity or the at least one of the plurality of coolant channels to increase a cooling surface area, and
when the internal cavity is utilized, a slotted or perforated jet impingement plate disposed within the liquid cold plate coincident with at least a portion of the internal cavity to generate targeted coolant jets or flows into the internal cavity.
